(19) United States
(12) Patent Application Publication
(10) Pub. No.: US 2015/0179404 A1
(43) Pub. Date: Jun. 25, 2015

(54) PLASMA PROCESSING APPARATUS

(71) Applicant: CANON KABUSHIKI KAISHA, Tokyo (JP)

(72) Inventor: Shunsuke Tamaya, Chigasaki-shi (JP)

(21) Appl. No.: 14/413,937

(22) PCT Filed: Aug. 16, 2013
(86) PCT No.: PCT/JP2013/072489

§ 371 Date: Jan. 9, 2015

(30) Foreign Application Priority Data
Aug. 21, 2012 (JP) 2012-182501
Jul. 29, 2013 (JP) 2013-156364

(51) Int. Cl. H01J 37/32

(52) U.S. Cl. CPC H01J 37/32055; H01J 37/32871; H01J 2237/332

(57) ABSTRACT

In a vacuum arc discharge deposition apparatus, an orifice plate having an opening is arranged in a state of being insulated from a magnetic field duct including at least one curved portion for transporting a deposition particle in the middle of the at least one curved portion, in which a neutral particle and a charged particle are removed by applying a voltage to the orifice plate.

### TECHNICAL FIELD

The present invention relates to a plasma processing apparatus, and more particularly, to a plasma processing apparatus employing a vacuum arc discharge.

### BACKGROUND ART

In recent years, a practical use of a thin film deposition technology based on a vacuum arc discharge has been progressing. For example, a deposition apparatus for finely depositing a protective film having excellent oxidation resistance and wear resistance has been put into practical use. The vacuum arc discharge is performed by setting a target material to a cathode and bringing an electrode of a ground potential into contact with the target or applying a high energy source such as an electron beam to the target material. This creates an arc discharge state of about several volts and several tens of amperes, to thereby generate an arc plasma.

The cathode material is subjected to a phase change into a plasma state of electrons and ions by the arc plasma. The generated ions are attracted to the cathode and collide with the cathode. In this manner, ions and electrons are further generated from the cathode material so that the plasma state is maintained.

The ions and the electrons that become deposition particles, which are generated by the above-mentioned processes, are guided and transported to a transport duct in a form of a plasma beam. A scanning duct for deflecting the plasma beam is further employed so as to uniformly deposit a film on a substrate or the like inside a vacuum deposition processing chamber as a deposition object.

Further, a voltage is supplied from an outside power source to the substrate in an insulated state with respect to the vacuum deposition processing chamber, and a film is deposited on the substrate. In this manner, a property of the deposited film is controlled.

However, in the above-mentioned vacuum arc discharge, it has been known that particles that cause adverse effects on the substrate are generated when the plasma is generated by the arc discharge.

When the generated particles are adhered to the substrate, the particles are deposited as a foreign substance, and hence the particles become a defect after depositing the film, which causes a serious problem. It has been known that the generated particles include neutral particles that are free of charges and charged particles that have charges. It has been also known that the charged particles having charges are likely to have negative charges.

To cope with this problem, PTL 1 describes that the duct for transporting the plasma generated by the arc discharge is branched into a duct through which the neutral particles travel straight and a duct through which the plasma beam travels in a curved manner to arrive at the substrate. With such a configuration, the neutral particles and the plasma beam are separated from each other, and the neutral particles are prevented from arriving at the substrate. The neutral particles that travel straight are trapped by a trapping unit.

Further, PTL 2 describes that, with respect to the particles having charges, a concentric cylindrical electrode is arranged between the duct and the substrate, to which a direct-current voltage or a direct-current voltage component of a high frequency power source of 10 V to 90 V is applied. With such a configuration, the charged particles are trapped by the concentric cylindrical electrode so that the amount of the charged particles arriving at the substrate can be reduced.

However, in the case of PTL 1, although the neutral particles can be removed, a duct for trapping the neutral particles needs to be provided and a trapping unit needs to be further installed. Therefore, a size of the apparatus is increased and a cost is also greatly increased.

Further, in the case of PTL 2, although the charged particles can be removed, the neutral particles that are free of charges are not influenced by the voltage applied to the concentric cylindrical structure, and hence sufficient suppression can hardly be obtained.

In general, in the deposition of a film employing the vacuum arc discharge, the transport of the ions to be deposited is performed by using a space including an electric field and a magnetic field. It has been said that a kinetic process of a charged particle in a magnetized plasma is governed by a bipolar diffusion phenomenon of the plasma. In the bipolar diffusion, an ion and an electron make a pair and move in such a manner that the electron is first diffused and then the ion is pulled later by the electric field and the magnetic field inside the transport duct. Therefore, the amount of the transported ions, i.e., a transport process of the deposited material is complicated. Therefore, the electrons and the ions need to be efficiently transported, which makes it difficult to control the transport amount. On the other hand, in the thin film deposition technology, a thickness of a film to be deposited and a time required to deposit the film up to the thickness, i.e., a deposition rate governs a function of the film, and hence control of the deposition rate is important. The vacuum arc discharge provides a high deposition rate compared to other deposition methods such as sputtering. Depending on the case, it may be requested to further increase the deposition rate to shorten the deposition time. When a film is deposited at a high speed, the deposited film may be damaged by a kinetic energy of the deposited ion, which may cause a defect. In this case, inversely, it is requested to decrease the deposition rate. Therefore, it is an issue to easily control the deposition rate in the vacuum arc discharge.

### CITATION LIST

### Patent Literature

PTL 1: Japanese Patent Application Laid-Open No. 2005-216575

PTL 2: Japanese Patent No. 3860954

### SUMMARY OF INVENTION

### Technical Problem

An object of the present invention is to sufficiently suppress neutral particles generated from a target, and at the same time, to remove charged particles, with a simple method. Another object of the present invention is to easily perform control of a deposition rate.

According to one embodiment of the present invention there is provided a plasma processing apparatus, including: a chamber configured to generate a plasma beam by ionizing a target arranged inside the chamber with an arc plasma generated by an arc discharge; a processing chamber configured to accommodate a substrate to be processed by the plasma beam; a duct including: one end continuously connected to the chamber; another end connected to the processing chamber; and at least one curved portion; a magnetic field generation unit configured to generate a magnetic field along a longitudinal direction of the duct; and a first orifice plate having an opening, which is arranged in a state of being electrically insulated from the duct at the at least one curved portion inside the duct. The first orifice plate is applied with a voltage by one of a direct-current voltage source and a high frequency voltage source.

Further features of the present invention will become apparent from the following description of exemplary embodiments with reference to the attached drawings.

### BRIEF DESCRIPTION OF DRAWINGS

FIG. 1 is a conceptual diagram of a plasma processing apparatus employing a vacuum arc discharge.

FIG. 2 is a cross-sectional view of a plasma processing apparatus according to a first embodiment of the present invention.

FIG. 3 is a schematic diagram of an orifice plate having a concentric opening according to the first embodiment.

FIG. 4 is a schematic diagram of a simulation model of a neutral particle according to the first embodiment.

FIG. 5 is a flowchart of a simulation of the neutral particle according to the first embodiment.

FIG. 6 is a graph showing a result of the simulation of the neutral particle according to the first embodiment.

FIG. 7 is a graph showing a result of the simulation of the neutral particle according to the first embodiment.

FIG. 8 is a schematic diagram of a simulation model of a charged particle according to the first embodiment.

FIG. 9 is a flowchart of a simulation of the charged particle according to the first embodiment.

FIG. 10 is a graph showing a result of the simulation of the charged particle according to the first embodiment.

FIGS. 11A and 11B are cross-sectional views of a plasma processing apparatus according to a second embodiment of the present invention.

FIGS. 12A and 12B are schematic diagrams of simulation models of a neutral particle according to the second embodiment.

FIG. 13 is a graph showing a result of a simulation of the neutral particle according to the second embodiment.

FIG. 14 is a graph showing a result of the simulation of the neutral particle according to the second embodiment.

FIG. 15 is a schematic diagram of a simulation model of a charged particle according to the second embodiment.

FIG. 16 is a graph showing a result of a simulation of the charged particle according to the second embodiment.

FIG. 17 is a cross-sectional view of a plasma processing apparatus according to a third embodiment of the present invention.

FIG. 18 is a cross-sectional view of the plasma processing apparatus according to the third embodiment.

FIG. 19 is a schematic diagram of a simulation model according to the third embodiment.

FIG. 20 is a graph showing a comparison of a deposition rate of a simulation according to the third embodiment.

FIG. 21 is a graph showing a comparison of the deposition rate of the simulation according to the third embodiment.

### DESCRIPTION OF EMBODIMENTS

Before describing embodiments of the present invention, a deposition principle of a plasma processing apparatus employing a vacuum arc discharge is described first.

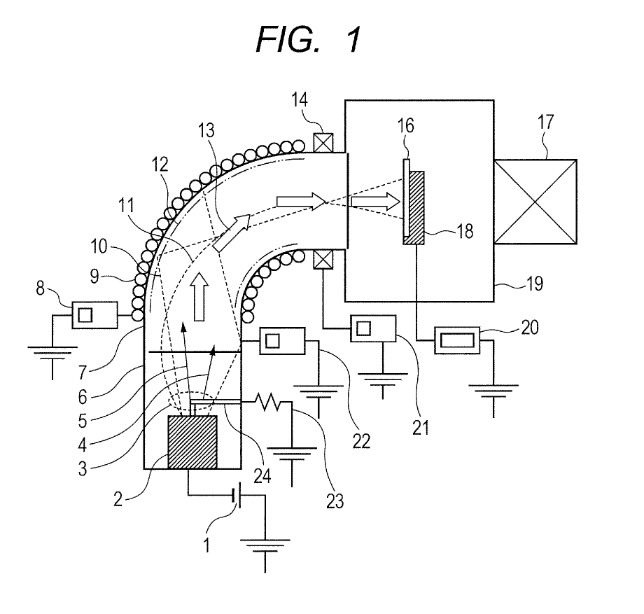

FIG. 1 is a conceptual diagram of a plasma processing apparatus employing a vacuum arc discharge. The plasma processing apparatus employing the vacuum arc discharge includes an arc discharge vacuum chamber 6 for generating an arc plasma by the vacuum arc discharge. A target 2 is arranged inside the arc discharge vacuum chamber 6, and a power source 1 for cathode is connected to the target 2 so as to define a cathode. Further, an anode configuration circuit 23 is connected to an arc discharge ignition source 24 so as to define an anode. The target 2 and the other components are set to a ground potential.

By bringing the target 2 and the arc discharge ignition source 24 into contact with each other, an insulation breakdown is generated, which leads to an arc discharge. Thus, an arc plasma 3 is generated. The target 2 that is ionized by the arc plasma 3 is pulled by an electric field generated by a voltage applied to the cathode, and sputters the target 2 that is the cathode material. The arc plasma 3 is maintained, and the target 2 is further ionized by a heat from the arc plasma 3.

A duct 7 is mounted on the arc discharge vacuum chamber 6. A bias power source 22 is connected to the duct 7 to apply a predetermined voltage to the duct 7. Further, by connecting a magnetic coil power source 8 to a magnetic coil 9 (magnetic field generation unit) arranged around the duct 7 and causing a current to flow through the magnetic coil 9, a magnetic field is generated inside the duct 7 along a longitudinal direction of the duct 7. An electron 4 is extracted along this magnetic field. Along with this, a generated ion 5 is also transported to an inside of the duct 7 and travels as a plasma beam 13. However, the bias power source 22 is optional.

A plasma scanning coil 14 for deflecting the plasma beam 13 and a scanning coil operation power source 21 for applying a voltage to the plasma scanning coil 14 are arranged at an end portion of the duct 7 on the opposite side to the arc discharge vacuum chamber 6. The plasma scanning coil 14 is constituted of multiple coils, and by adjusting a voltage applied to each of the coils, a deflection direction of the plasma beam 13 can be controlled. With this configuration, the entire surface of a substrate 16 can be scanned and irradiated with the plasma beam 13 to deposit the film.

A deposition processing chamber 19 including a vacuum pump 17 is continuously connected to the duct 7. The arc discharge vacuum chamber 6, the duct 7, and the deposition processing chamber 19 are decompressed into a predetermined pressure by the vacuum pump 17 so as to make the discharge easy.

A stage 18 is provided inside the deposition processing chamber 19 to hold the substrate (substrate to be processed) 16. By irradiating the substrate 16 with the ion 5 in the plasma beam 13 transported through the duct 7, the film can be deposited on the substrate 16.

The substrate 16 is arranged in a state of being insulated from the deposition processing chamber 19 and the stage 18, and in some cases, the substrate 16 is configured to be applied with a voltage by a substrate bias power source 20.

Normally, a cylindrical protective plate 12 having a complicated surface profile with protrusions of several millimeters in size or a fiber shape is mounted along an internal surface inside the duct 7. At the same time, a neutral particle 10 or a charged particle 11 is generated from the target that is subjected to sputtering by the arc plasma 3. The neutral particle 10 is randomly scattered inside the apparatus while being reflected at a wall surface inside the apparatus. The charged particle 11 is scattered inside the apparatus while being influenced by the electric field and the magnetic field generated inside the apparatus.

### First Embodiment

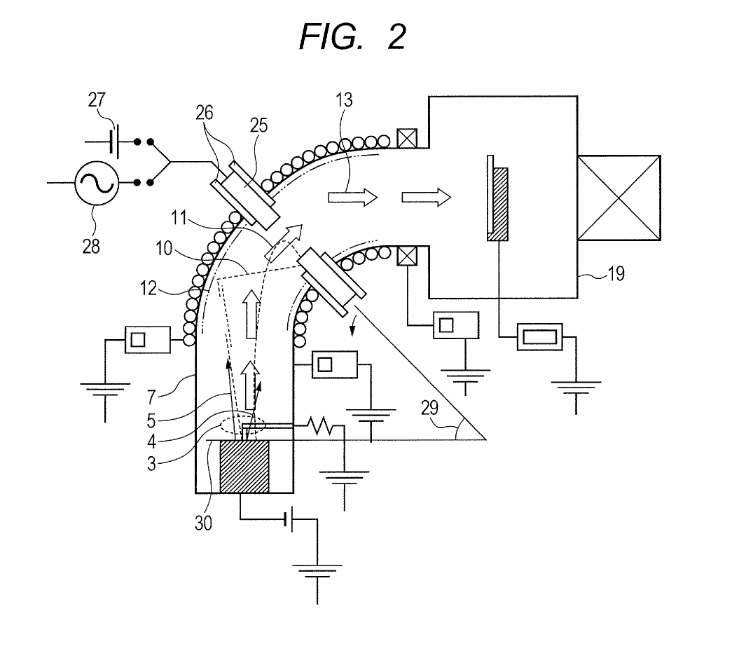

FIG. 2 is a cross-sectional view of a plasma processing apparatus employing a vacuum arc discharge according to a first embodiment of the present invention. In the subsequent drawings, the same reference symbols as those of FIG. 2 represent the same contents as those of FIG. 2.

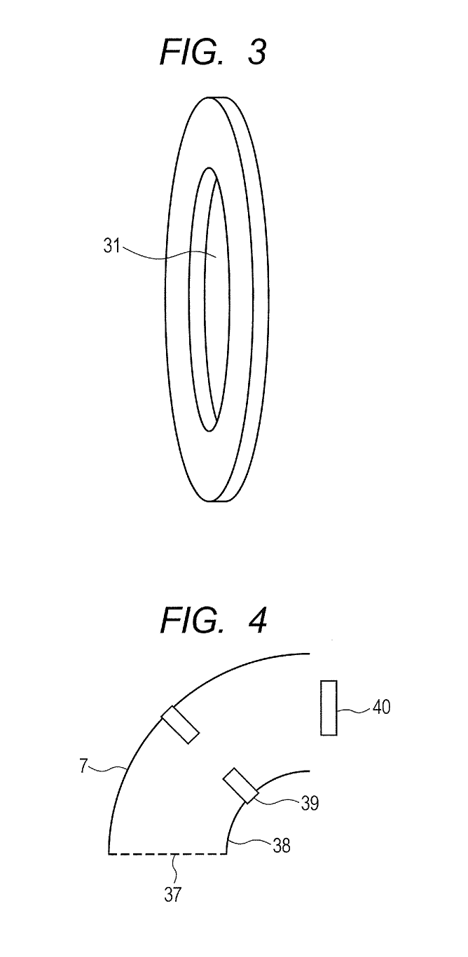

The duct (magnetic field duct) 7 includes at least one curved portion, and an orifice plate (first orifice plate) 25 having an opening 31 that defines a concentric circle with the duct 7, which is illustrated in FIG. 3, is arranged inside the duct 7 and in the middle of the curved portion. Note that, the opening 31 of the orifice plate 25 is not necessarily to define a concentric circle with the duct 7, but can also be configured as multiple openings. However, considering the deposition rate and the like, it is preferred to define a concentric circle with the duct 7.

The orifice plate 25 is arranged in a state of being insulated from the duct 7. A material of the orifice plate 25 is a metal or an insulation material. When the material of the orifice plate 25 is the metal, the orifice plate 25 is connected to the duct 7 via an insulation orifice plate 26 formed of an insulation material to obtain an insulation from the duct 7.

The orifice plate 25 is configured to be connected to a direct-current voltage source 27 or a high frequency voltage source 28. When the orifice plate 25 is formed of the metal, the direct-current voltage source 27 is employed, and when the orifice plate is formed of the insulation material, the high frequency voltage source 28 is employed.

A part of the neutral particle 10 generated by the arc plasma (plasma generation unit) 3 is trapped by the duct 7 and the protective plate 12 due to the curved shape of the duct 7 and effects of the protective plate 12 inside the duct 7. A major part of the remaining neutral particle 10 is trapped by the orifice plate 25 having the concentric opening, which is arranged inside the duct 7 and in the middle of the curved portion.

By arranging the orifice plate 25 to block a path of the neutral particle 10 with respect to a collision and a reflection of the neutral particle 10 due to the curved shape, the neutral particle 10 can be efficiently removed.

A surface of the target from which the electron 4 and the ion 5 are extracted by the arc plasma 3 is taken as a reference surface 30, and then with respect to the reference surface 30, the orifice plate 25 can be mounted at an arbitrary mounting angle 29.

Further, a scattering path of the charged particle 11 is deflected by an electric field generated by a direct-current component of a voltage applied to the orifice plate 25 from the direct-current voltage source 27 or the high frequency voltage source 28.

### Example 1

FIG. 4 is a schematic diagram of a calculation model of the duct 7 from which a behavior of the neutral particle 10 is simulated. The calculation model illustrated in FIG. 4 is a simplified configuration of the configuration illustrated in FIG. 2 for simulating the behavior of the neutral particle 10. In the simulation, a particle generation spot 37 (corresponding to the reference surface 30 that is the surface of the target) where the neutral particle 10 was generated and a particle arrival evaluation surface 40 representing the deposition processing chamber 19 were prepared.

An orifice plate 39 having a concentric opening illustrated in FIG. 3 was arranged inside the duct 7 and in the middle of the curved portion. A predetermined adsorption ratio was set on a duct wall surface 38 of the duct 7, and the calculation was performed by setting the adsorption ratio corresponding to portions of the orifice plate 39 and the duct wall surface 38, and changing a value of the adsorption ratio.

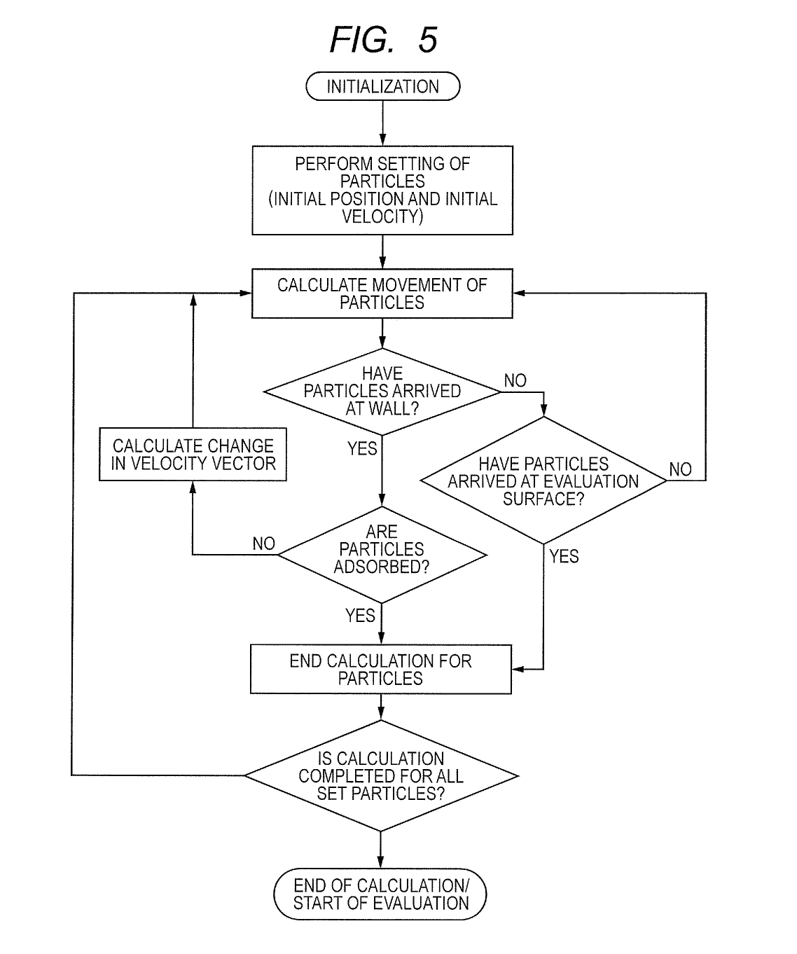

FIG. 5 is a flowchart for simulating a behavior of the neutral particle. The internal portion of the duct was in a vacuum condition, and hence the calculation was performed by using rarefied gas analysis. The simulation was performed by using a RGS3D which is a product of PEGASUS software Inc. After initializing internal variables of the simulation by using uniform random numbers, particles corresponding to the neutral particles 10 having a random velocity distribution were randomly arranged at the particle generation spot 37 of the neutral particles 10 by using random numbers, and positions of the particles were traced as time advanced.

Each of the neutral particles 10 virtually performed a motion based on the rarefied gas theory. The neutral particles 10 arrived at the duct wall surface 38 and the orifice plate 39 were stochastically adsorbed based on the adsorption ratio set for each portion. The position of each of the neutral particles 10 was traced, and then the number of neutral particles 10 that arrived at the particle arrival evaluation surface 40 was counted. At the time when the calculation was completed for all the particles to be calculated, the simulation was ended and the evaluation was performed. A ratio of the number of particles arrived at the particle arrival evaluation surface 40 to the number of particles arranged at the particle generation spot 37 where the neutral particles are generated was defined as a particle arrival ratio, and this particle arrival ratio was evaluated. The simulation was performed with a diameter of the opening of the orifice plate 39 and the mounting angle 29 of the orifice plate 39 as the variables.

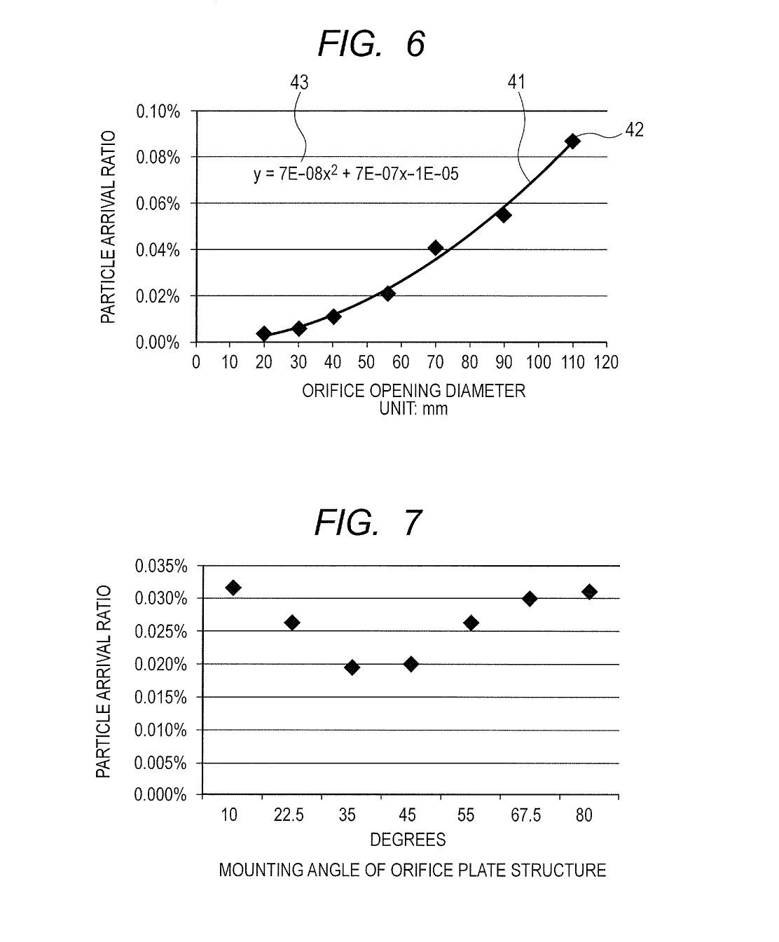

FIG. 6 is a graph showing a result of evaluating the neutral particle arrival ratio with respect to a size of the opening of the orifice plate. The mounting angle 29 of the orifice plate 39 at this time was set to 45 degrees from the reference surface 30.

In FIG. 6, the horizontal axis represents the diameter of the opening of the orifice plate and the vertical axis represents the particle arrival ratio. A point 42 in the graph indicates the actual simulation result, and a solid line 41 indicates an approximate curve. A variable x in an approximate expression 43 in the graph corresponds to the diameter of the opening of the orifice plate, and a value y indicates the particle arrival ratio. Further, “E” in the graph is a symbol indicating an exponential.

As indicated by the approximate expression 43, the arrival ratio of the neutral particle is increased in proportional to a square of the opening of the orifice plate. Therefore, by reducing the diameter of the opening of the orifice plate, the neutral particle 10 can be efficiently prevented from arriving at the substrate 16. In order to suppress the arrival ratio of the neutral particle to 0.03% or lower, it is preferred to set the diameter of the opening of the orifice plate to 60 mm or smaller. Further, in order to suppress the arrival ratio of the neutral particle to 0.02% or lower, it is preferred to set the diameter of the opening of the orifice plate to 50 mm or smaller. However, considering the deposition rate, it is preferred that the diameter of the opening of the orifice plate be 20 mm or larger.

FIG. 7 is a graph showing a result of evaluating the arrival ratio of the neutral particle with respect to the mounting angle of the orifice plate. The graph shows a result obtained when the diameter of the opening of the orifice plate was set to 50 mm. In FIG. 7, the horizontal axis represents the mounting angle 29 of the orifice plate 25 from the reference surface 30 illustrated in FIG. 2, and the vertical axis represents the particle arrival ratio. From FIG. 7, it can be found that the particle arrival ratio of the neutral particle 10 arriving at the substrate 16 can be suppressed to 0.03% or lower for sure by setting the mounting angle 29 of the orifice plate 25 from the reference surface 30 in a range from 22.5 degrees to 55 degrees. Further, in order to suppress the particle arrival ratio to 0.02% or lower for sure, it is preferred to set the mounting angle 29 in a range from 35.0 degrees to 45.0 degrees.

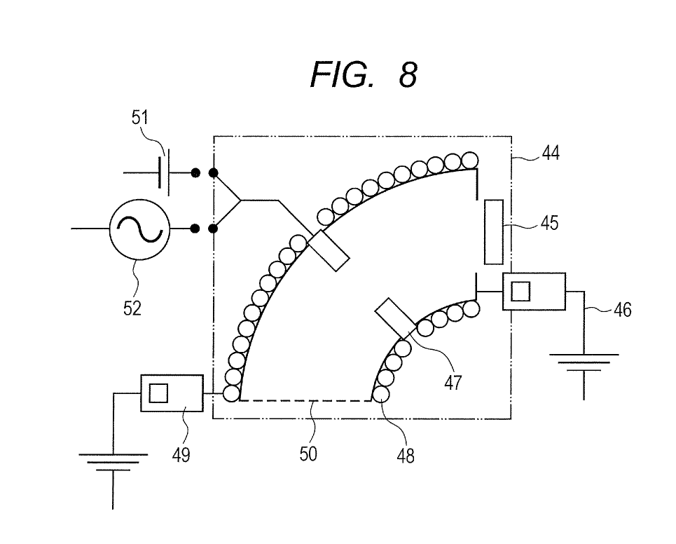

FIG. 8 is a schematic diagram of a calculation model of the duct for simulating a behavior of the charged particle. The calculation model illustrated in FIG. 8 is a simplified configuration of the configuration illustrated in FIG. 2 for simulating the behavior of the charged particle 11. In the simulation, a particle generation spot 50 where the charged particle 11 was generated and a particle arrival evaluation surface 45 representing the deposition processing chamber 19 were prepared. The charged particle 11 is influenced by the electric field and the magnetic field, and hence a space for analyzing the electric field and the magnetic field was prepared as an area 44 including the shape of the duct.

In order to perform electric field analysis, a duct bias power source 46 was modeled. Further, an orifice plate 47 representing the orifice plate 25 was modeled, and a direct-current voltage source 51 or a high frequency voltage source 52 was connected to the orifice plate 47 to apply a voltage to the orifice plate 47. In addition, in order to perform magnetic field analysis, a magnetic coil 48 and a magnetic coil bias power source 49 were modeled.

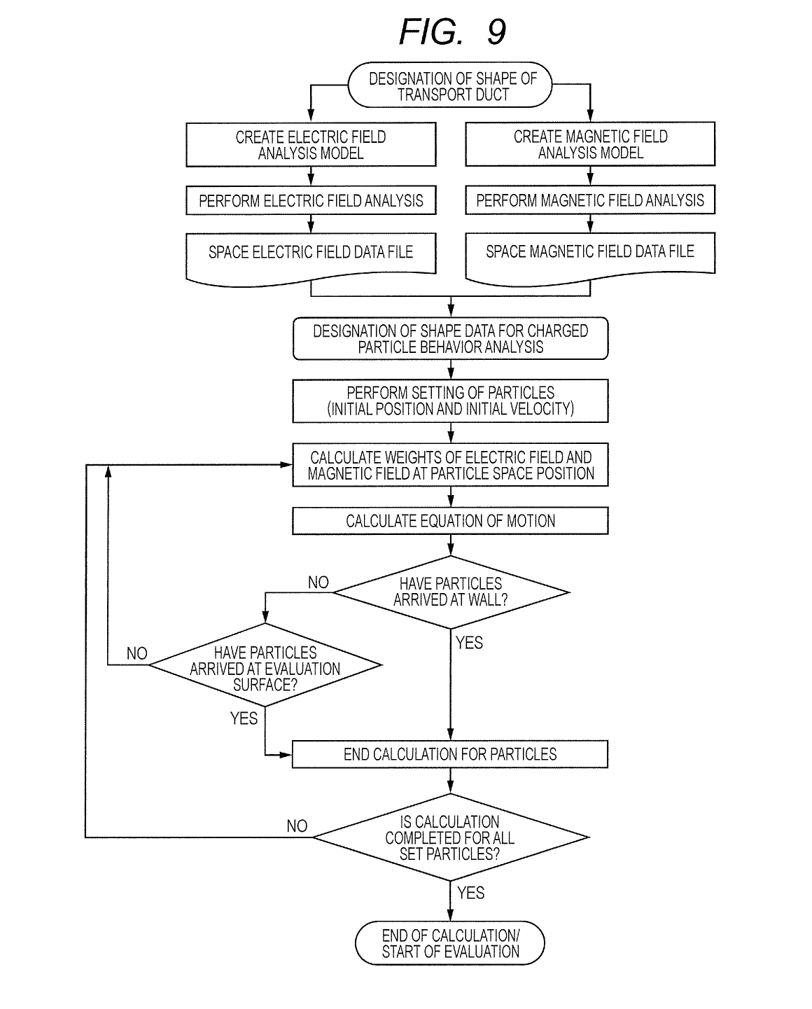

FIG. 9 is a flowchart of a simulation of the behavior of the charged particle. After setting the shape of the duct to be calculated, voltages were applied respectively to the duct bias power source 46 and the orifice plate 47 in the area 44 including the shape of the duct to set a condition for generating the electric field, and then the electric field analysis was performed.

With respect to the same shape, a current was caused to flow through to the magnetic coil 48 of the duct via the magnetic coil bias power source 49 to set a condition for generating the magnetic field, and then the magnetic field analysis was performed. The analysis was performed by using an electric field analysis software ELF-magic/ELFIN, which is a product of ELF Inc. The behavior of the charged particle 11 was simulated by using pieces of information of the electric field and the magnetic field calculated from the two analyses. Virtual particles to which a charged particle comparable energy generated by the arc plasma 3 was randomly applied by using normal random numbers were randomly arranged on the particle generation spot 50 of the charged particle 11 by using uniform random numbers.

It was assumed that the motion of the charged particle 11 was determined by the Lorentz formula. The charge in the Lorentz formula was handled as an elementary charge, assuming that the charge had a negative polarity. The pieces of information of the electric field and the magnetic field calculated before exist at nodes on a predetermined lattice.

On the other hand, the particle to be calculated exists at a position that does not depend on the lattice at every hour. Therefore, every time the particle position was moved, positions of eight nearby points from each lattice node and contributions of the electric field and the magnetic field were calculated by a linear approximation. The contributions of the electric field and the magnetic field calculated by the linear approximation were taken as the electric field and the magnetic field at the points to solve the Lorentz formula.

Under such a circumstance, the motion of the virtual charged particle was traced for every predetermined time, and traces of the particle that arrived at the wall surface of the duct 7, the orifice plate 47, and the particle arrival evaluation surface 45 were ended at the arrival points.

This operation was performed for all the arranged virtual charged particles, and the total number of the virtual charged particles arrived at the particle arrival evaluation surface 45 was counted. A ratio of the number of the particles arrived at the particle arrival evaluation surface to the number of particles arranged at the particle generation spot 50 of the charged particle 11 was defined as a particle arrival ratio and evaluated. This simulation was performed with the mounting angle 29 of the orifice plate 47 and the voltage applied to the orifice plate 47 as variables.

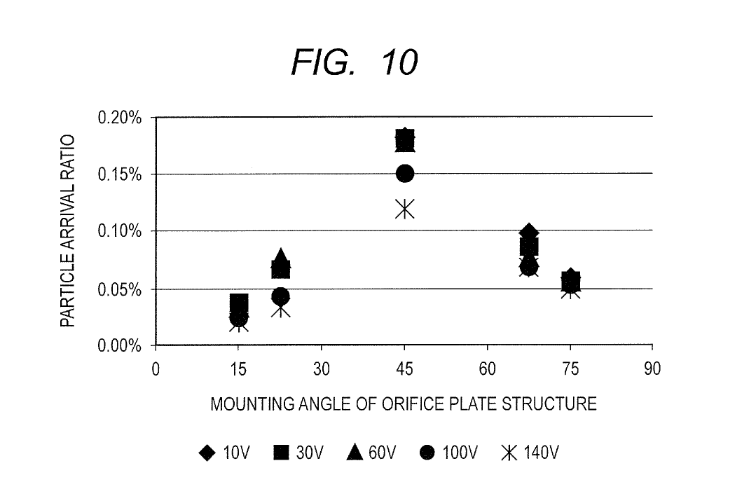

FIG. 10 is a graph showing a result of evaluating the charged particle arrival ratio with respect to the mounting angle 29 of the orifice plate 47 illustrated in FIG. 8 and the applied voltage. The graph shows a result obtained when the diameter of the opening of the orifice plate 47 was set to 50 mm. In FIG. 10, the horizontal axis represents the mounting angle 29 of the orifice plate 47 from the reference surface 30, and the vertical axis represents the particle arrival ratio. Each legend represents the voltage applied to the orifice plate 47. In a range of the mounting angle 29 from 15 degrees to 75 degrees where the experiment was conducted, the particle arrival ratio was 0.20% or lower in a range of the applied voltage from 10 V to 140 V, and thus, it can be found that the charged particle can be sufficiently suppressed in those ranges. The arrival ratio of the charged particle takes the maximum value when the mounting angle 29 from the reference surface 30 is 45 degrees.

On the other hand, when the applied voltage exceeds 100 V, the particle arrival ratio is decreased for each mounting angle. This is because a relationship between the electric field and the magnetic field in the Lorentz formula is reversed before and after 100 V with the shape and the geometric size of the calculation model.

Specifically, calculating a value of the electric field with the applied voltage and a distance between the electrodes, calculating a value of the magnetic field from the Ampere's law, and calculating and comparing a cross product of an initial velocity of the charged particle applied by the arc discharge give about 103 V. This value is a threshold for reversing the influences of the electric field and the magnetic field.

That is, when the voltage applied to the orifice plate 47 is increased, an operation of the electric field becomes more conspicuous than an operation of the magnetic field in the Lorentz formula, which becomes a force to deflect a trajectory of the charged particle. Therefore, in order to efficiently remove the charged particle, it is preferred to set the voltage applied to the orifice plate 47 to 100 V or higher.

As described above, in the first embodiment, by setting the mounting angle 29 from the reference surface 30 to 22.5 degrees to 55 degrees, both the neutral particle and the charged particle can be sufficiently prevented from arriving at the substrate 16.

### Second Embodiment

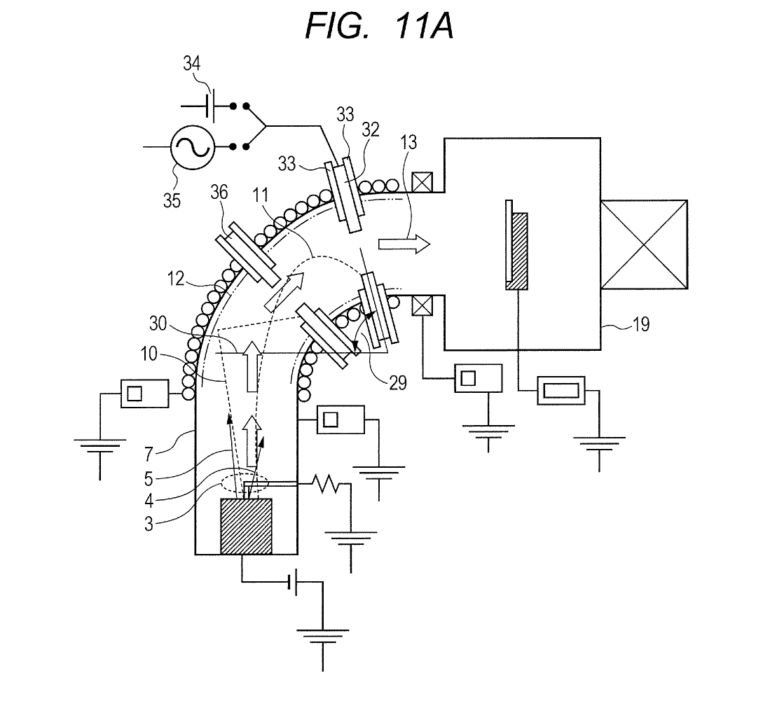

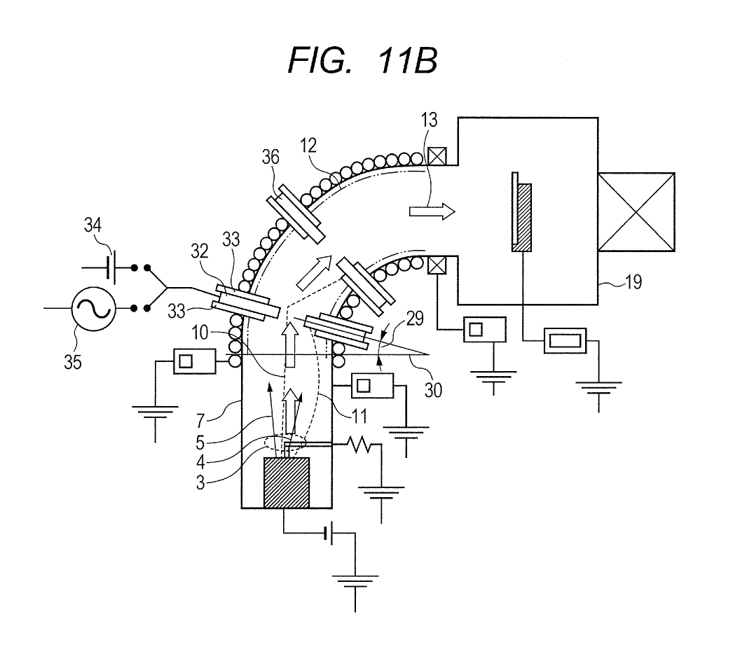

FIGS. 11A and 11B are cross-sectional views illustrating a shape of a duct according to a second embodiment of the present invention. In the second embodiment, the function of suppressing the neutral particle and the function of suppressing the charged particle in the first embodiment are separated from each other.

The duct 7 includes at least one curved portion, and an orifice plate (second orifice plate) 36 having the concentric opening 31, which is illustrated in FIG. 3, is arranged inside the duct 7 and in the middle of the curved portion. The second orifice plate 36 is arranged in a state of being insulated from the duct 7. A material of the second orifice plate 36 is a metal or an insulation material.

A part of the neutral particle 10 generated by the arc plasma 3 is trapped by the duct 7 and the protective plate 12 due to the curved shape of the duct 7 and effects of the protective plate 12 inside the duct 7. A major part of the remaining neutral particle 10 is trapped by the second orifice plate 36 having the concentric opening, which is arranged inside the duct 7 and in the middle of the curved portion.

By arranging the second orifice plate 36 to block a path of the neutral particle 10 with respect to a collision and a reflection of the neutral particle 10 due to the curved shape, the neutral particle 10 can be efficiently removed.

A surface from which the electron 4 and the ion 5 are extracted by the arc plasma 3 into the plasma beam 13 shape is taken as the reference surface arc plasma flow-in surface 30, and then with respect to the reference surface 30, the second orifice plate 36 can be mounted at the arbitrary mounting angle 29. The removal of the neutral particle 10 is effective when the mounting angle 29 with respect to the reference surface 30 is in a range from 22.5 degrees and 55 degrees, preferably a range from 35 degrees to 45 degrees.

The charged particle removal mechanism is arranged as a separate orifice plate from the second orifice plate 36. In order to remove the charged particle, a third orifice plate 32 having the concentric opening, which is illustrated in FIG. 3, is arranged inside the duct 7 and in the middle of the curved portion. The third orifice plate 32 is mounted in a state of being insulated from the duct 7 and the second orifice plate 36 for removing the neutral particle 10.

When the material of the third orifice plate 32 is the metal, the third orifice plate 32 is connected to the duct 7 via an insulation orifice plate 33 formed of an insulation material to obtain an insulation from the duct 7. The third orifice plate 32 is configured to be connected to a direct-current voltage source 34 or a high frequency voltage source 35. When the third orifice plate 32 is formed of the metal, the direct-current voltage source 34 is employed, and when the third orifice plate 32 is formed of the insulation material, the high frequency voltage source 35 is employed. A scattering path of the charged particle is deflected by an electric field generated by a voltage applied to the direct-current voltage source 34 or the high frequency voltage source 35.

The third orifice plate 32 having the removal mechanism can take the maximum effect by being mounted near an inlet or an outlet of the duct 7 inside the duct 7 and in the middle of the curved portion. FIG. 11A illustrates an example in which the third orifice plate 32 having the removal mechanism is arranged on the outlet side of the duct 7. FIG. 11B illustrates an example in which the third orifice plate 32 having the removal mechanism is arranged on the inlet side of the duct 7. By applying a voltage of 100 V or higher to the third orifice plate 32 having the removal mechanism, the charged particle can be efficiently removed.

### Example 2

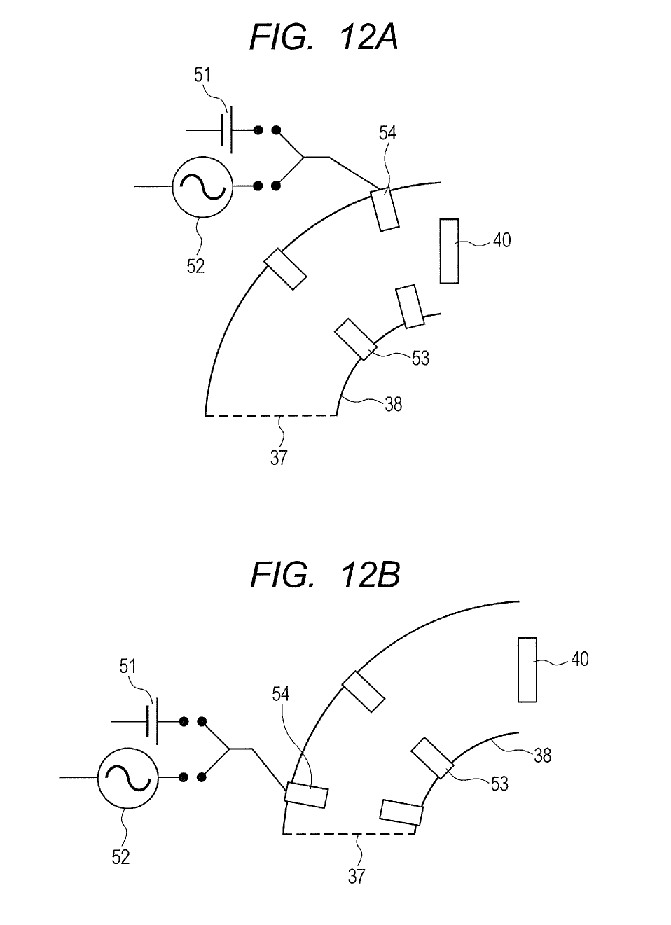

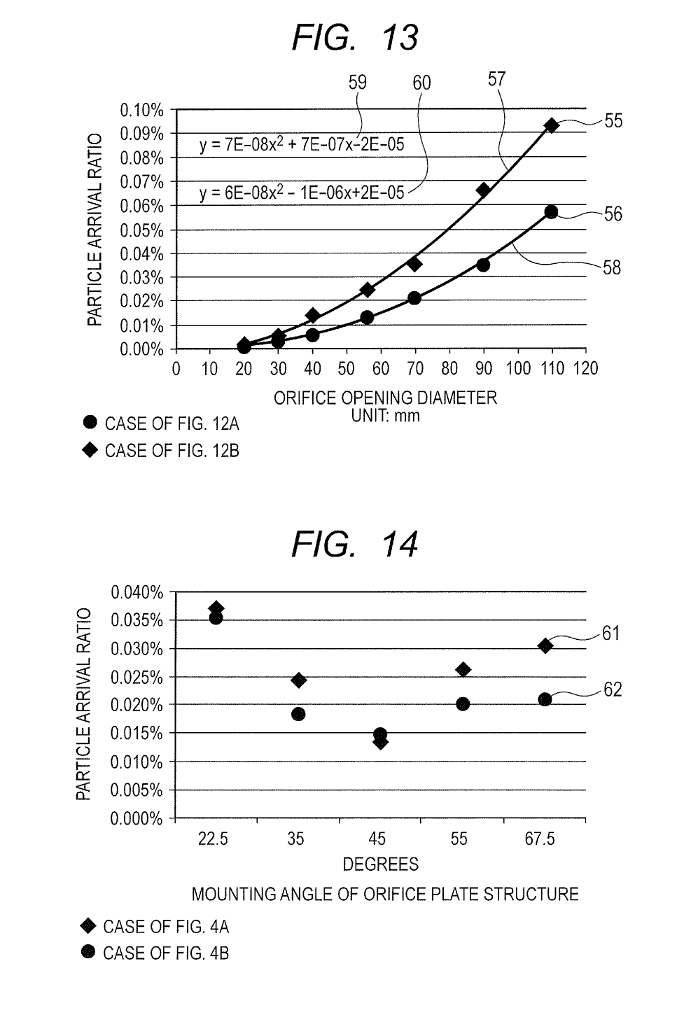

FIGS. 12A and 12B are schematic diagrams of calculation models of the duct 7 from which a behavior of the neutral particle 10 is simulated. The calculation models illustrated in FIGS. 12A and 12B are simplified configurations of the configurations illustrated in FIGS. 11A and 11B for simulating the behavior of the neutral particle 10. FIG. 12A corresponds to a mode of FIG. 11A, and FIG. 12B corresponds to a mode of FIG. 11B.

In the simulation, the particle generation spot 37 (corresponding to the reference surface 30 serving as the surface of the target) where the neutral particle 10 was generated and the particle arrival evaluation surface 40 representing the deposition processing chamber 19 were prepared. An orifice plate 53 corresponding to the second orifice plate 36 having the concentric opening illustrated in FIG. 3 was arranged inside the duct 7 and in the middle of the curved portion. Further, an orifice plate 54 corresponding to the third orifice plate 32 was separately arranged.

In FIG. 12A, the analysis was performed by setting the mounting angle of the orifice plate 54 with respect to the particle generation spot 37 to a position of 80 degrees with respect to the reference surface 30 serving as the surface of the target. In FIG. 12B, the analysis was performed by setting the mounting angle of the orifice plate 54 with respect to the particle generation spot 37 to a position of 10 degrees with respect to the reference surface 30 serving as the surface of the target. A predetermined adsorption ratio was set on the duct wall surface 38 of the duct 7, and the calculation was performed by setting the adsorption ratio corresponding to portions of the orifice plate 53 and the duct wall surface 38, and changing a value of the adsorption ratio. The simulation was performed by using a RGS3D which is a product of PEGASUS software Inc. The simulation was performed following the flowchart illustrated in FIG. 5.

FIG. 13 is a graph showing a result of evaluating the neutral particle arrival ratio with respect to a diameter of the opening of each of the orifice plates 53 and 54. The graph shows a result obtained when the mounting angle 29 of the orifice plate 53 illustrated in FIG. 12A or FIG. 12B is set to 45 degrees, where the horizontal axis represents the diameter of the opening of the orifice plate 53, and the vertical axis represents the particle arrival ratio. Points 55 and 56 in the graph indicate actual simulation results based on the modes illustrated in FIG. 12A and FIG. 12B, respectively. Solid lines 57 and 58 indicate approximated curves corresponding to the simulation results 55 and 56, respectively.

A variable x in approximate expressions 59 and 60 in the graph corresponds to the diameter of the opening of the orifice plate, and a value y indicates the particle arrival ratio. Further, “E” in the graph is a symbol indicating an exponential. As indicated by the approximate expressions 59 and 60, the arrival ratio of the neutral particle is increased in proportional to a square of the opening of the orifice plate. Therefore, by reducing the diameter of the opening of the orifice plate, the neutral particle 10 can be efficiently prevented from arriving at the substrate 16.

In order to suppress the arrival ratio of the neutral particle to 0.03% or lower, in the case of the mode illustrated in FIG. 12A, it is preferred to set the diameter of the opening of the orifice plate to 80 mm or smaller. Further, in the case of the mode illustrated in FIG. 12B, it is preferred to set the diameter of the opening of the orifice plate to 60 mm or smaller. Further, in order to suppress the arrival ratio of the neutral particle to 0.02% or lower, in the case of the mode illustrated in FIG. 12A, it is preferred to set the diameter of the opening of the orifice plate to 70 mm or smaller. Further, in the case of the mode illustrated in FIG. 12B, it is preferred to set the diameter of the opening of the orifice plate to 50 mm or smaller. However, considering the deposition rate, it is preferred that the diameter of the opening of the orifice plate be 20 mm or larger.

FIG. 14 is a graph showing a result of evaluating the arrival ratio of the neutral particle 10 with respect to the mounting angle of the orifice plate 53. In the evaluation, the diameter of the opening of the orifice plate 53 was set to 50 mm. In FIG. 14, the horizontal axis represents the mounting angle 29 of the orifice plate 53 from the reference surface 30, and the vertical axis represents the particle arrival ratio. Solid diamonds in the graph indicate a result of the analysis for the mode illustrated in FIG. 12A. Solid circles indicate a result of the analysis for the mode illustrated in FIG. 12B.

From FIG. 14, it can be found that the particle arrival ratio of the neutral particle 10 arriving at the substrate 16 can be suppressed to 0.03% or lower for sure by setting the mounting angle 29 of the second orifice plate 36 from the reference surface 30 in a range from 35.0 degrees to 55.0 degrees. Further, in order to suppress the particle arrival ratio to 0.02% or lower for sure, it is preferred to set the mounting angle 29 in a range from 40.0 degrees to 45.0 degrees. Further, it can be found that the particle arrival ratio becomes the minimum value when the mounting angle 29 is in a range from 35 degrees to 45 degrees.

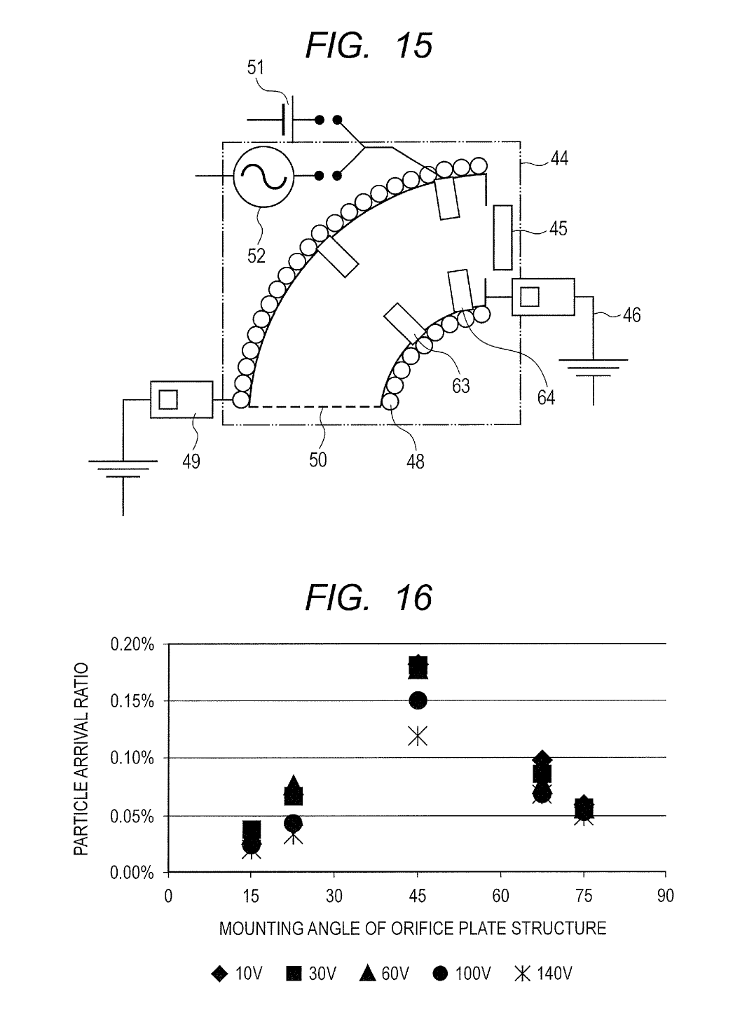

FIG. 15 is a schematic diagram of a calculation model of the duct for simulating a behavior of the charged particle. The calculation model illustrated in FIG. 15 is a simplified configuration of the configuration illustrated in FIG. 11A or 11B for simulating the behavior of the charged particle 11. In the simulation, the particle generation spot 50 where the charged particle 11 was generated and the particle arrival evaluation surface 45 representing the deposition processing chamber 19 were prepared. The charged particle 11 is influenced by the electric field and the magnetic field, and hence a space for analyzing the electric field and the magnetic field was prepared as the area 44 including the shape of the duct.

In order to perform electric field analysis, the duct bias power source 46 was modeled. Further, an orifice plate 63 representing the second orifice plate 36 was modeled. The orifice plate 63 was mounted at a fixed angle of 45 degrees with respect to the particle generation spot 50. In a separated manner from the orifice plate 63, an orifice plate 64 representing the third orifice plate 32 was modeled.

The mounting angle of the orifice plate 64 can be arbitrarily set with respect to the particle generation spot 50. Further, the orifice plate 64 can be connected to the direct-current voltage source 51 and the high frequency voltage source 52 to be applied with a voltage. In addition, in order to perform magnetic field analysis, the magnetic coil 48 and the magnetic coil bias power source 49 were modeled.

FIG. 16 is a graph showing a result of evaluating the arrival ratio of the charged particle with respect to the mounting angle 29 of the orifice plate 64 and the applied voltage. The graph shows a result obtained when the diameter of the opening of the orifice plate 64 was set to 50 mm. In FIG. 16, the horizontal axis represents the mounting angle 29 of the orifice plate 64 from the reference surface 30, and the vertical axis represents the particle arrival ratio. Each legend represents the voltage applied to the orifice plate 64.

In FIG. 16, in a range of the mounting angle 29 from 15 degrees to 75 degrees where the experiment was conducted, the particle arrival ratio was 0.20% or lower in a range of the applied voltage from 10 V to 140 V, and thus, it can be found that the charged particle can be sufficiently suppressed in those ranges. Further, it can be found that the particle arrival ratio of the charged particle 11 is reduced by mounting the orifice plate 64 near an inlet or an outlet of the duct 7. Therefore, in the range of the applied voltage from 10 V to 140 V, in order to suppress the particle arrival ratio to 0.10% or lower, it is preferred to set the mounting angle 29 to 25 degrees or small or in a range from 65 degrees to 90 degrees.

On the other hand, when the applied voltage exceeds 100 V, the particle arrival ratio is decreased for each mounting angle. This is because a relationship between the electric field and the magnetic field in the Lorentz formula is reversed before and after 100 V with the shape and the geometric size of the calculation model. Specifically, calculating a value of the electric field with the applied voltage and a distance between the electrodes, calculating a value of the magnetic field from the Ampere's law, and calculating and comparing a cross product of a velocity of the charged particle applied by the arc discharge give about 103 V. This value is a threshold for reversing the influences of the electric field and the magnetic field.

That is, when the voltage applied to the orifice plate 64 is increased, an operation of the electric field becomes more conspicuous than an operation of the magnetic field in the Lorentz formula, which becomes a force to deflect a trajectory of the charged particle. Therefore, in order to efficiently remove the charged particle, it is preferred to set the voltage applied to the orifice plate 64 to 100 V or higher.

As described above, in the second embodiment, by setting the mounting angle of the second orifice plate 36 from the reference surface 30 to 35 degrees to 55 degrees, both the neutral particle and the charged particle can be sufficiently prevented from arriving at the substrate 16. Further, by setting the mounting angle of the third orifice plate 32 from the reference surface 30 to 25 degrees or smaller or in a range from 65 degrees to 90 degrees, both the neutral particle and the charged particle can be sufficiently prevented from arriving at the substrate 16.

### Third Embodiment

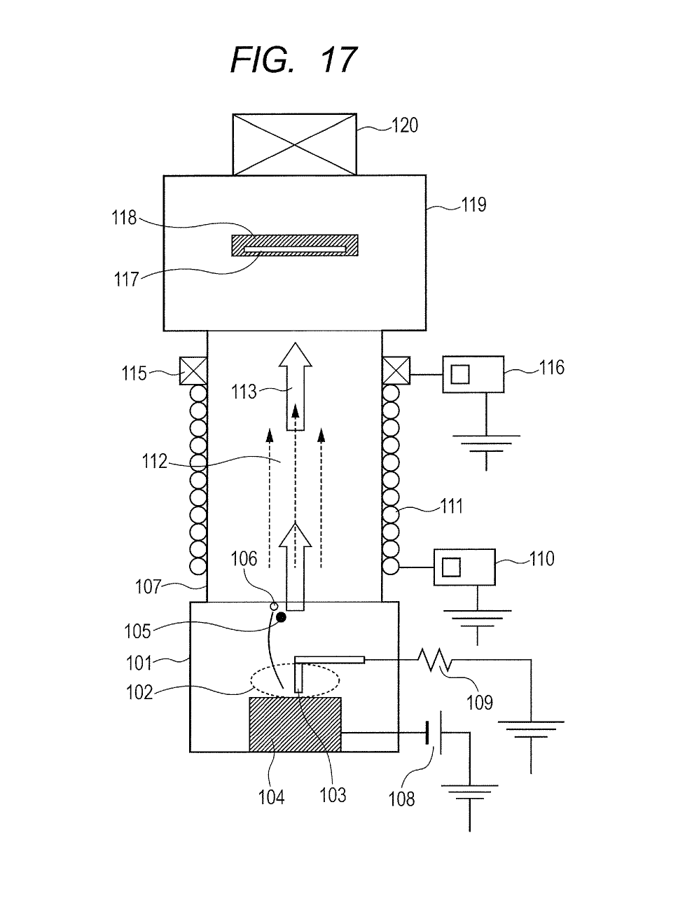

FIG. 17 is a conceptual diagram of a plasma processing apparatus employing the vacuum arc discharge according to a third embodiment of the present invention. In the plasma processing apparatus employing the vacuum arc discharge, a target 104 is arranged inside a vacuum chamber 101 that is the plasma generation unit, and a cathode power source 108 is connected to the target 104 so as to define a cathode. Further, an anode configuration circuit 109 is connected to an arc discharge ignition source 103 so as to define an anode. The components other than the arc discharge ignition source 103 are set to a ground potential. By bringing the target 104 and the arc discharge ignition source 103 into contact with each other, an insulation breakdown is generated, which leads to an arc discharge. Thus, an arc plasma 102 is generated. The target 104 that is ionized by the arc plasma 102 is pulled by an electric field generated by a voltage applied to the cathode, and sputters the target 104 that is the cathode material. The arc plasma 102 is maintained, and the target 104 is further ionized by a heat from the arc plasma 102.

On the other hand, by connecting a magnetic coil power source 110 to a magnetic coil 111 arranged around a duct 107 and causing a current to flow through the magnetic coil 111, a magnetic field 112 is generated inside the duct along a longitudinal direction of the duct. An electron heading for the magnetic field 112 among electrons 106 of the arc plasma is extracted from the vacuum chamber 101 to the duct 107. On the other hand, an ion 105 is extracted in such a manner that the electron 106 is first extracted and then the ion 105 is extracted following the electron 106 by being pulled by a negative electric field generated by the electron 106 based on the bipolar diffusion principle. As a result, the electron 106 and the ion 105 attract each other by their electric fields (bipolar electric fields) and move together. With this operation, the electron 106 and the ion 105 move forward as a plasma beam 113 and transported.

A plasma beam scanning coil 115 for deflecting the plasma beam 113 is arranged at an end portion of the duct 107 on the opposite side to the arc discharge vacuum chamber 101. A scanning coil power source 116 is connected to the scanning coil 115. A deposition processing chamber 119 including a vacuum pump 120 is continuously connected to the duct 107. The plasma generating unit 101, the duct 107, a plasma beam scanning duct 114, and the deposition processing chamber 119 are decompressed into a predetermined pressure by the vacuum pump 120. A stage 118 is provided inside the deposition processing chamber 119, to arrange a deposition object 117 (for example, a substrate). By irradiating the deposition object 117 with the ion 105 in the plasma beam 113 transported through the duct 107, a film can be deposited on the deposition object 117 (for example, a substrate).

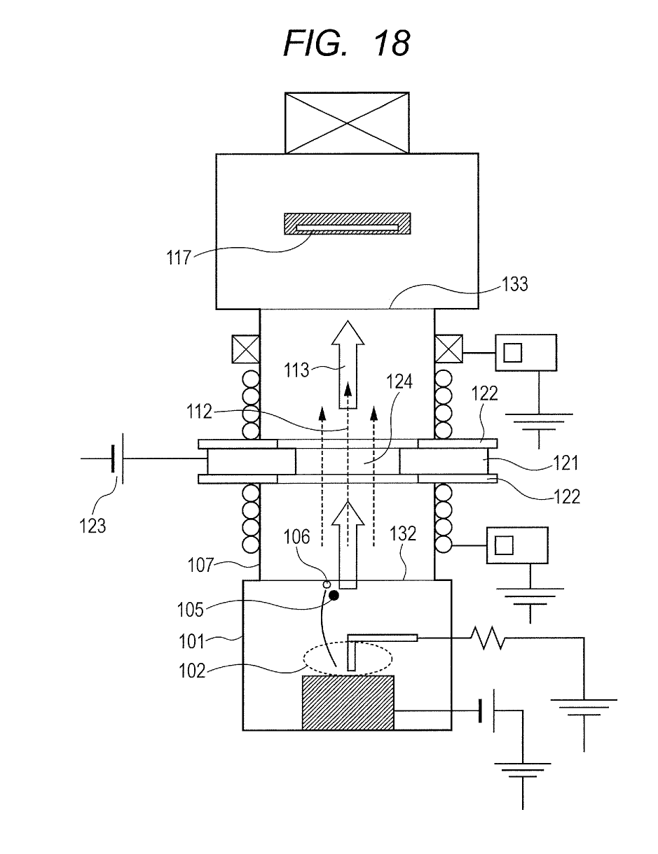

FIG. 18 is a schematic diagram of the plasma processing apparatus illustrated in FIG. 17, in which a fourth orifice plate 121 having an opening 124 is arranged.

The duct 107 illustrated in FIG. 18 is formed in a straight shape, and the fourth orifice plate 121 having the opening 124 is arranged inside and in the middle of the duct 107. A cross section of the duct is circular, and it is preferred that a cross section of the opening 124 of the fourth orifice plate 121 and the cross section of the duct be concentric. The opening 124 is formed of a hole or an opened portion, which can be the same as or different from the cross section of the duct.

The fourth orifice plate 121 is arranged in a state of being insulated from the duct 107. A material of the fourth orifice plate 121 is a metal. The fourth orifice plate 121 is connected to the duct 107 via an insulation member 122 formed of an insulation material to obtain an insulation from the duct 107. A voltage applying unit 123 for applying a direct-current voltage to the fourth orifice plate 121 is provided, and hence the fourth orifice plate 121 is configured to be connected to a direct-current voltage source. The electron 106 and the ion 105 generated from the plasma generation unit 101 by the arc plasma 102 are transported to the inside of the duct 107 as the plasma beam 113 by the bipolar diffusion phenomenon, and arrive at the deposition object 117 (for example, a substrate). At this time, the electron 106 performs a motion supplemented by a magnetic flux of the parallel magnetic field 112, and hence the plasma travels along the magnetic flux of the parallel magnetic field 112.

The fourth orifice plate 121 can be mounted at an arbitrary position in a direction orthogonal to the magnetic field 112 inside the duct 107. In the third embodiment, a position where a change of the arrival ratio of the electron 106 and the ion 105 at the deposition object 117 (for example, a substrate), i.e., control of the deposition rate can be most effectively performed is an intermediate position between the inlet and the outlet of the duct. An intermediate portion between a plasma inlet 132 and a plasma outlet 133 of the duct 107 is a position on the center side from the plasma inlet 132 and the plasma outlet 133 by 20% or more of a length of the duct 107, and a position on the center side by 30% or more of the length of the duct 107 is preferred.

A result of performing a verification with the plasma processing apparatus according to the third embodiment illustrated in FIG. 18 is described below.

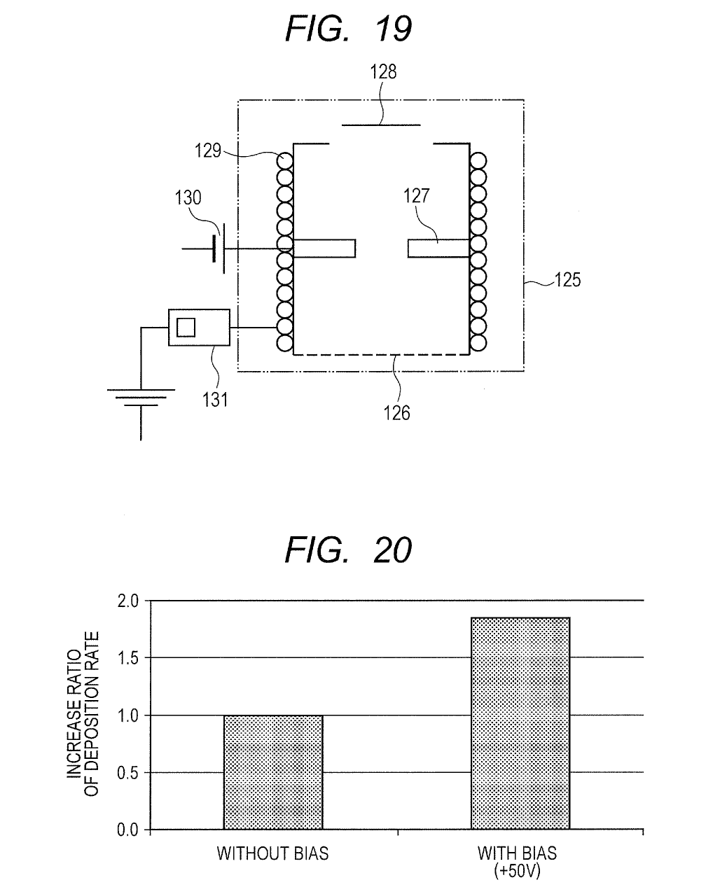

FIG. 19 is a schematic diagram of a calculation model of the duct to simulate a trajectory of the electron 106. In the vacuum arc discharge, the electron 106 and the ion 105 that is deposited scatter as a pair by the bipolar diffusion. Therefore, with an assumption that the trajectory of the electron 106 is virtually the same as the trajectory of the ion 105 and the arrival amount of the electron 106 is proportional to the arrival amount of the ion 105, the calculation and the evaluation are performed. The calculation model illustrated in FIG. 19 is a simplified configuration of the configuration illustrated in FIG. 18 for simulating the trajectory of the electron 106. In the simulation, an electron generation spot 126 of the electron 106 and an electron arrival evaluation surface 128 representing the deposition processing chamber 119 were prepared. An orifice plate 127 corresponding to the fourth orifice plate 121 having the concentric opening is arranged in the middle of the duct 107. The electron 106 is influenced by the electric field and the magnetic field, and hence a space for analyzing the electric field and the magnetic field is prepared as an area 125 including the shape of the duct. The fourth orifice plate 127 is configured to be connected to a direct-current voltage source 130 to apply a voltage to the fourth orifice plate 127, and the calculation of the electric field is performed. Further, in order to perform magnetic field analysis, a magnetic coil 129 and a magnetic coil power source 131 are modeled. When the electron 106 arrives at the duct 107 and the fourth orifice plate 127, the electron 106 becomes a current and disappears from the space, and hence the electron is excluded from the calculation on site. The trajectory analysis is performed for a plurality of electrons, and thus the evaluation is performed.

Under such a circumstance, the motion and the moving trajectory of the electron are traced for every predetermined time, and the trace is ended for the electron that arrived at the wall surface of the duct 107, the fourth orifice plate 127, and the electron arrival evaluation surface 128. This operation is performed for all the electrons arranged, and the total number of the electrons arrived at the electron arrival evaluation surface 128 is counted. A ratio is obtained by dividing the number of the electrons arrived at the electron arrival evaluation surface 128 by the number of electrons arranged at the electron generation spot 126. In the transport by the bipolar diffusion, it is expected that the trajectory of the electron is virtually the same as the trajectory of the ion. Therefore, the obtained ratio is taken as the arrival rate of the ion, and the evaluation is performed by taking this arrival rate as the deposition rate. This simulation was performed with the mounting position of the fourth orifice plate 127 inside the duct and the voltage applied to the fourth orifice plate 127 as variables.

FIG. 20 is a graph showing an increase ratio of the deposition rate with respect to presence and absence of the voltage application to the fourth orifice plate 127. A value when only the magnetic field is applied to the duct is set to “1”. For example, when a direct-current voltage of +50 V is applied to the structure, it indicates that about 1.8 times of increase ratio of the deposition rate can be obtained. This is because the electrons scattered in the duct are pulled by the fourth orifice plate 127 to which a positive potential is applied so that a probability of the electrons passing through the opening 124 of the fourth orifice plate 127 is increased.

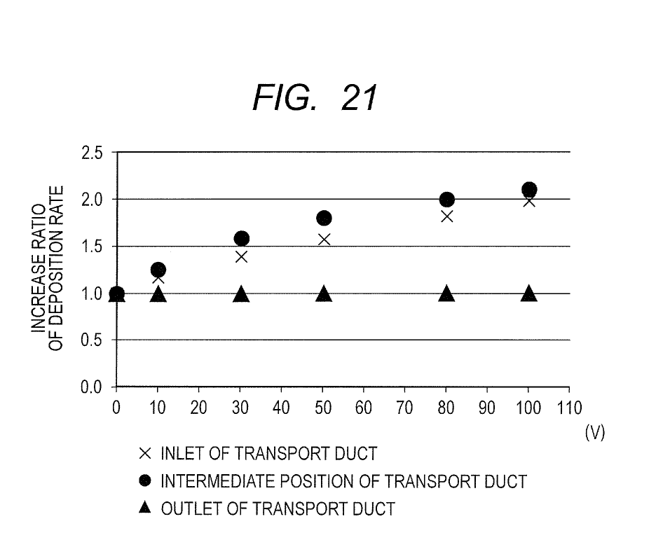

FIG. 21 is a graph showing a result of the simulation when the mounting position of the fourth orifice plate 127 inside the duct and the voltage applied for each position are taken as variables. In FIG. 21, the horizontal axis represents the voltage applied to the fourth orifice plate 127 via the direct-current voltage source 130. The vertical axis represents a ratio of the arrival ratio of the electron when the voltage is applied to the arrival ratio of the electron corresponding to the ion when the no voltage is applied. The vertical axis shows a change of the deposition rate with presence and absence of the voltage and a magnitude of the voltage. The result shows that, when the fourth orifice plate 127 is arranged at the outlet of the duct 107, there is no effect of applying the voltage, and thus the deposition rate cannot be controlled. When the fourth orifice plate 127 is arranged at the inlet of the duct 107 and when the fourth orifice plate 127 is arranged at an intermediate position between the inlet and the outlet, the arrival ratio is increased with an increase of the magnitude of the voltage. Therefore, the result indicates that, by changing the voltage applied to the fourth orifice plate 127, the deposition rate can be controlled.

Further, the result indicates that mounting the fourth orifice plate 127 at the intermediate position between the inlet and the outlet of the duct 107, rather than mounting the fourth orifice plate 127 at the inlet of the duct 107, can increase the change of the deposition rate, and thus the deposition rate can be effectively controlled.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-182501, filed Aug. 21, 2012, and Japanese Patent Application No. 2013-156364, filed Jul. 29, 2013, which are hereby incorporated by reference herein in their entirety.

1. A plasma processing apparatus comprising:
a chamber configured to generate a plasma beam by ionizing a target arranged inside the chamber with an arc plasma generated by an arc discharge;
a processing chamber configured to accommodate a substrate to be processed by the plasma beam;
a duct comprising:
one end connected to the chamber;
another end connected to the processing chamber; and
at least one curved portion;
a magnetic field generation unit configured to generate a magnetic field along a longitudinal direction of the duct; and
a first orifice plate having an opening, which is arranged in a state of being electrically insulated from the duct at the at least one curved portion inside the duct,
wherein the first orifice plate is applied with a voltage by one of a direct-current voltage source and a high frequency voltage source.

2. The plasma processing apparatus according to claim 1, wherein an angle between a surface of the target and a surface of the first orifice plate is in a range from 22.5 degrees to 55 degrees.

3. The plasma processing apparatus according to claim 1, wherein an angle between a surface of the target and a surface of the first orifice plate is in a range from 35 degrees to 45 degrees.

4. The plasma processing apparatus according to claim 1, wherein a diameter of the opening of the first orifice plate is in a range from 20 mm to 60 mm.

5. The plasma processing apparatus according to claim 1, wherein the magnetic field generation unit comprises a magnetic coil arranged on an outer circumferential portion of the duct.

6. The plasma processing apparatus according to claim 1, further comprising a vacuum exhaust unit configured to decompress the chamber, the duct, and the processing chamber.

7. The plasma processing apparatus according to claim 1, further comprising a plasma scanning coil arranged at an end portion of the duct on the processing chamber side and configured to deflect the plasma beam.

8. The plasma processing apparatus according to claim 1, further comprising a cylindrical protective plate arranged inside the duct.

9. A plasma processing apparatus comprising:
a chamber configured to generate a plasma beam by ionizing a target arranged inside the chamber by an arc discharge;
a processing chamber configured to accommodate a substrate to be processed by the plasma beam;
a duct comprising:
one end connected to the chamber;
another end connected to the processing chamber; and
at least one curved portion;
a magnetic field generation unit configured to generate a magnetic field along a longitudinal direction of the duct; and
a second orifice plate and a third orifice plate each having an opening, which are arranged in a state of being electrically insulated from the duct at the at least one curved portion inside the duct,
wherein the third orifice plate is applied with a voltage by one of a direct-current voltage source and a high frequency voltage source.

10. The plasma processing apparatus according to claim 9, wherein an angle between a surface of the target and a surface of the second orifice plate is in a range from 22.5 degrees to 55 degrees.

11. The plasma processing apparatus according to claim 10, wherein an angle between a surface of the target and a surface of the third orifice plate is one of 25 degrees or less and in a range from 65 degrees to 90 degrees.

12. (canceled)
